(19) United States
(12) Patent Application Publication
(10) Pub. No.: US 2026/0369994 A1
(43) Pub. Date: Nov. 19, 2026

(54) POWER SUPPLY UNIT OF TELECOM POWER SYSTEM

(71) Applicant: Delta Electronics (Thailand) Public Company Limited, Samutprakarn (TH)

(72) Inventor: Phichej Cheevanantachai, Samutprakarn (TH)

(21) Appl. No.: 19/133,928

(22) PCT Filed: Dec. 26, 2023
(86) PCT No.: PCT/IB2023/063246

§ 371 Date: May 29, 2025

Related U.S. Application Data
(60) Provisional application No. 63/435,425, filed on Dec. 27, 2022.
(60) Provisional application No. 63/466,751, filed on May 16, 2023.

(51) Int. Cl. H02J 1/082; H02M 1/00; H02M 1/32; H02M 1/36; H02M 3/00; H02M 3/335

(52) U.S. Cl. CPC H02J 1/082; H02M 1/0009; H02M 1/32; H02M 1/36; H02M 3/003; H02M 3/33576

(57) ABSTRACT

A power supply unit of a telecom power system is provided. The power supply unit includes first and second ports, a processor, an amplifier unit and a communication module. The first port provides a first voltage and includes a first output terminal and a first ground terminal. The second port provides a second voltage and includes a second output terminal and a second ground terminal. The second voltage is lower than the first voltage, and the second ground terminal is isolated from the first ground terminal. The processor has a reference point electrically connected to the second ground terminal and is configured for system control, communication, and controlling power provided by the first port. The amplifier unit has a reference point electrically connected to the first ground terminal. The communication module is configured to transmit signals between the processor and the amplifier unit with electrical isolation.

### CROSS-REFERENCE TO RELATED APPLICATION

This application claims the priorities of U.S. Provisional Application No. 63/435,425 filed on Dec. 27, 2022, entitled “GOLDEN FINGER LAYOUT DESIGN AND CIRCUIT CONFIGURATION OF TELECOM POWER SYSTEM FOR M-CRPS AND PoE” and U.S. Provisional Application No. 63/466,751 filed on May 16, 2023, entitled “GOLDEN FINGER LAYOUT DESIGN AND CIRCUIT CONFIGURATION OF TELECOM POWER SYSTEM FOR CRPS AND M-CRPS AND PoE”. The entire contents of the above-mentioned patent applications are incorporated herein by reference for all purposes.

### FIELD OF THE INVENTION

The present disclosure relates to a power supply unit, and more particularly to a power supply unit of a telecom power system.

### BACKGROUND OF THE INVENTION

Most telecom power systems have two difference platforms for power and signal outputs, and all the power supply units need to compliance with system communication protocol (e.g., I2C, CAN BUS or UART protocol).

In the first platform, regarded as non-isolation platform, there is no isolation between the high voltage circuit and the low voltage and communication circuits.

In the second platform, regarded as isolation platform, there is an isolation between the high voltage circuit and the low voltage and communication circuits. The second platform requires two difference system grounds and needs more spacing on creepage and clearance between the high voltage circuit and the low voltage and communication circuits.

In order to be adapted to both the isolation application and the non-isolation application, the telecom power system needs the power supply units with two different platforms, and the corresponding output connectors also need to be separated. Consequently, the design complexity and the cost of system is increased.

Therefore, there is a need of providing a power supply unit of a telecom power system in order to overcome the drawbacks of the conventional technologies.

### SUMMARY OF THE INVENTION

The present disclosure provides a power supply unit of a telecom power system which is applicable for both the isolation application and the non-isolation application, thereby decreasing reducing the design complexity and the cost.

In accordance with an aspect of the present disclosure, a power supply unit of a telecom power system is provided. The power supply unit includes a first port, a second port, a processor, an amplifier unit and a communication module. The first port is configured to provide a first voltage and includes a first output terminal and a first ground terminal. The second port is configured to provide a second voltage and includes a second output terminal and a second ground terminal. The second voltage is lower than the first voltage, and the second ground terminal is isolated from the first ground terminal. The processor has a reference point electrically connected to the second ground terminal and is configured for system control, communication, and controlling power provided by the first port. The amplifier unit has a reference point electrically connected to the first ground terminal. The communication module is configured to transmit signals between the processor and the amplifier unit with electrical isolation.

### BRIEF DESCRIPTION OF THE DRAWINGS

FIG. 1 schematically shows a telecom power system with non-isolation platform;

FIG. 2 schematically shows a telecom power system with isolation platform;

FIG. 3 is a schematic block diagram illustrating a power supply unit of a telecom power system according to a first embodiment of the present disclosure;

FIG. 4 schematically shows an implementation of the power supply unit of FIG. 3;

FIG. 5 is a schematic block diagram illustrating a power supply unit of a telecom power system according a second embodiment of the present disclosure;

FIG. 6 is a schematic view illustrating a power supply connector of a power supply unit according to an embodiment of the present disclosure; and

FIG. 7 schematically shows various kinds of system connectors that the power supply connector of the present disclosure is applicable for.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

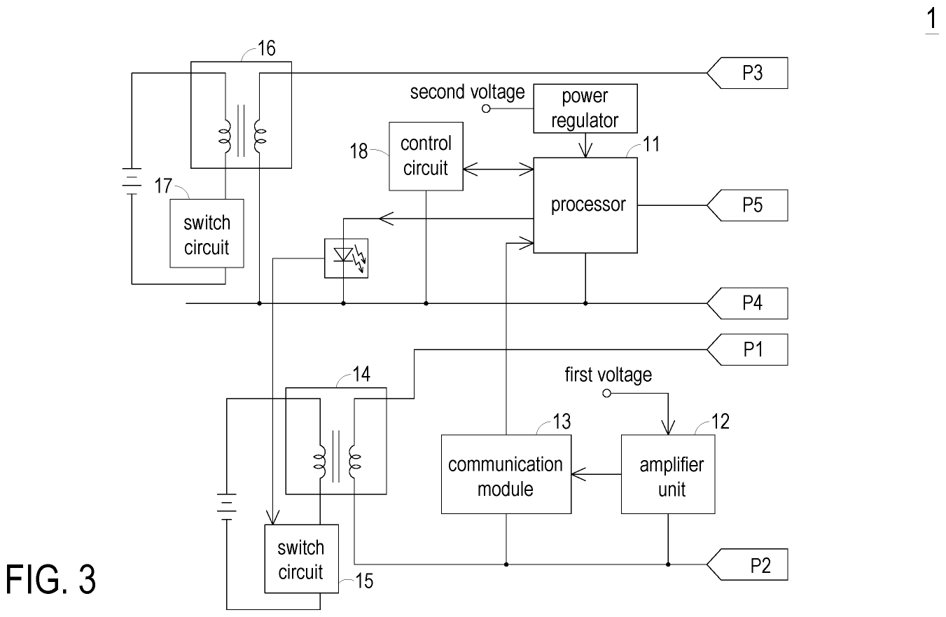

FIG. 3 is a schematic block diagram illustrating a power supply unit of a telecom power system according to a first embodiment of the present disclosure. As show in FIG. 3, the power supply unit 1 includes a first port, a second port, a processor 11, an amplifier unit 12 and a communication module 13. The first port is configured to provide a first voltage and includes a first output terminal P1 and a first ground terminal P2. The second port is configured to provide a second voltage and includes a second output terminal P3 and a second ground terminal P4. The second voltage is lower than the first voltage. For example, the first voltage may be 54V or 48V, and the second voltage may be 12V or a standby voltage of 12V. In an embodiment, for an isolation implementation, the second ground terminal P4 may be isolated from the first ground terminal P2. In other words, the circuit related to the first voltage may be electrically isolated from the circuit related to the second voltage.

The processor 11 has a reference point electrically connected to the second ground terminal P4, and the processor 11 is configured for system control, communication and controlling the output power provided by the first port and second port, for example, the processor 11 may work as both of a PWM feedback controller and a housekeeping and system communication controller, but not limited thereto. The processor 11 may be used for control and feedback of the first port and CAN (controller area network) bus for system communication and power supply unit warning status signals and system control logic to power supply. Regarding the communication function, the processor 11 may further include a communication port P5. The communication port 5 is configured to communicate signals between the telecom power system and the power supply unit 1. In an embodiment, through the communication port P5, the processor 11 may receive the control logic of starting or shutting down the power supply unit 1 from the telecom power system, and also the processor 11 may report the operation status of the power supply unit 1 to the telecom power system based on a bus communication protocol. As an example, the processor 11 includes a DSP (digital signal processing) MCU (microcontroller unit), but not limited thereto.

The amplifier unit 12 has a reference point electrically connected to the first ground terminal P2. In an embodiment, the amplifier unit 12 includes at least one operational amplifier, and a reference point of the at least one operational amplifier is electrically connected to the first ground terminal P2. The communication module 13 is configured to transmit signals between the processor 11 and the amplifier unit 12 with electrical isolation.

Consequently, in the power supply unit 1, the circuits related to the first voltage (i.e., the high voltage) are electrically isolated from the circuits related to the second voltage (i.e., the low voltage) and the communication signals.

In addition, the power supply unit 1 may further include a first converter, which is used to convert a voltage from a high voltage source into the first voltage provided to the first port. In an embodiment, an isolated transformer 14 and a switch circuit 15 may be included in the first converter. The processor 11 may control the power provided at the first port by providing at least one control signal to the switch circuit 15. In an embodiment, the processor 11 provides the control signal to the switch circuit 15 through an optical isolation PWM driver (OPTO isolation PWM driver) or a driver transformer. For example, the optical isolation PWM driver (OPTO isolation PWM driver) or the driver transformer includes a transmitter and a receiver, the processor 11 outputs the control signal for switch circuit 15 to the transmitter, and the receiver is triggered by the transmitter to transmit the control signal to drive at least the primary switches in the switch circuit 15, but not limited thereto.

Similarly, the power supply unit 1 may further include a second converter, which is used to convert a voltage from a high voltage source into the second voltage provided to the second port. In an embodiment, an isolated transformer 16 and a switch circuit 17 may be included in the second converter. In an embodiment, the power supply unit 1 further includes a control circuit 18 electrically connected to the processor 11, the control circuit 18 reports the status of the power provided by the second port, and the processor 11 provides a control signal to the control circuit 18 for controlling the power provided by the second port (e.g., ON/OFF).

Regarding the output of the first port, the power supply unit 1 may have some detection circuits for status detection. The amplifier unit 12 is adapted to interface between the communication module 13 and the detection circuits. Specifically, the amplifier unit 12 is electrically connected to the detection circuits and provides the detection results to the communication module 13, and the communication module 13 transmits the detection results to the processor 11 with electrical isolation.

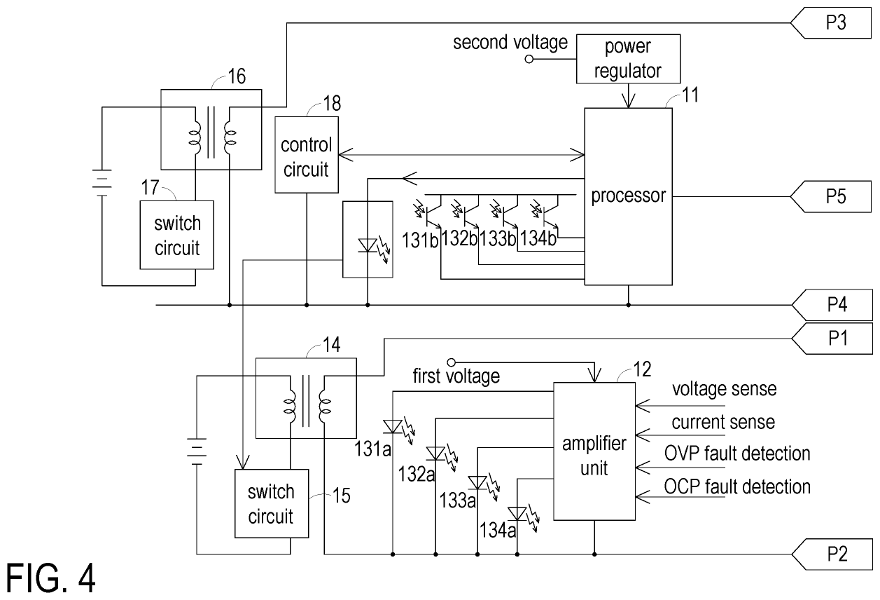

FIG. 4 schematically shows an implementation of the power supply unit of FIG. 3. As shown in FIG. 4, the communication module 13 may include at least one opto-coupler for transmitting the detection result with electrical isolation, and each opto-coupler includes a transmitter and a receiver electrically connected to the amplifier unit 12 and the processor 11 respectively. The detection circuits for detecting the status of the power provided by the first port may include at least one of a voltage sensing circuit, a current sensing circuit, an OVP fault detection circuit, an OCP fault detection circuit, and a short-circuit detection circuit, but not exclusively. For example, in this implementation, the amplifier unit 12 receives the detection results from the voltage sensing circuit, the current sensing circuit, the OVP fault detection circuit and the OCP fault detection circuit and provides to four opto-coupler of the communication module. The transmitter 131a and the receiver 131b of an opto-coupler of the communication module 13 transmits the voltage detection result to the processor 11 with electrical isolation. The transmitter 132a and the receiver 132b of an opto-coupler of the communication module 13 transmits the current detection result to the processor 11 with electrical isolation. The transmitter 133a and the receiver 133b of an opto-coupler of the communication module 13 transmits the OVP fault detection result to the processor 11 with electrical isolation. The transmitter 134a and the receiver 134b of an opto-coupler of the communication module 13 transmits the OCP fault detection result to the processor 11 with electrical isolation. It is noted that the number of the at least one operational amplifier of the amplifier unit 12 and the number of the at least one opto-coupler of the communication module 13 are not limited and may be determined according to the number of the detection circuits.

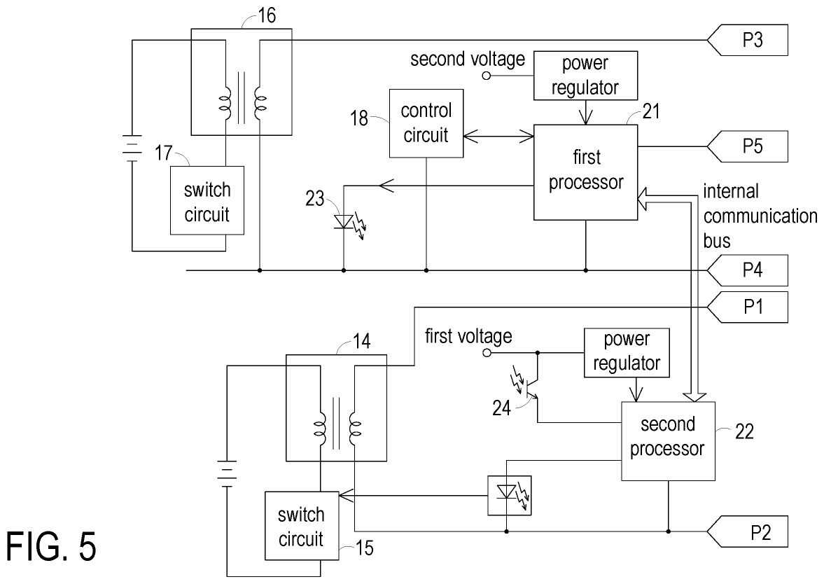

FIG. 5 is a schematic block diagram illustrating a power supply unit of a telecom power system according a second embodiment of the present disclosure. In FIG. 5, the components corresponding to those of FIG. 3 are designated by the same numeral references, and thus detailed descriptions thereof are omitted herein. In the first embodiment as shown in FIG. 3, the amplifier unit 12 reports the status of the power provided by the first port to the processor 11, and the processor 11 is adapted to control the whole power supply unit 1. By contrast, in the second embodiment shown in FIG. 5, the power supply unit 2 utilizes a first processor 21 and a second processor 22 for controlling the powers provided by the second port and the first port respectively. In particular, as shown in FIG. 5, the power supply unit 2 includes the first processor 21 and the second processor 22. The first processor 21 has a reference point electrically connected to the second ground terminal P4. Similar with the processor 11 of the first embodiment, the first processor 21 is also used for communication, and the first processor 21 may receive the status of the power provided by the second port from the control circuit 18 and provides a control signal to the control circuit 18 for controlling the power provided by the second port (e.g., ON/OFF). The second processor 22 has a reference point electrically connected to the first ground terminal P2, and the second processor 22 controls the power provided at the first port by providing a control signal to the switch circuit 15. For example, the first processor 21 includes a microcontroller unit, and the second processor 22 includes a digital signal processing microcontroller unit. In an embodiment, the second processor 22 may provide the control signal to the switch circuit 15 through an optical isolation PWM driver (OPTO isolation PWM driver) or a driver transformer. In specific, the optical isolation PWM driver (OPTO isolation PWM driver) or the driver transformer includes a transmitter and a receiver, the second processor 22 outputs the control signal to the transmitter, and the receiver in the switch circuit 15 is triggered by the transmitter to transmit the control signal to switches of the switch circuit 15.

In addition, the first processor 21 may provide a control signal to the second processor 22 through a transmitter 23 and a receiver 24 of an opto-coupler, and the control signal is used to control the ON/OFF of the first voltage. In an embodiment, the second processor 22 communicates with the first processor 21 through an internal communication bus of the power supply unit 2, and the second processor 22 reports the status of the power provided by the first port to the first processor 21 through the internal communication bus.

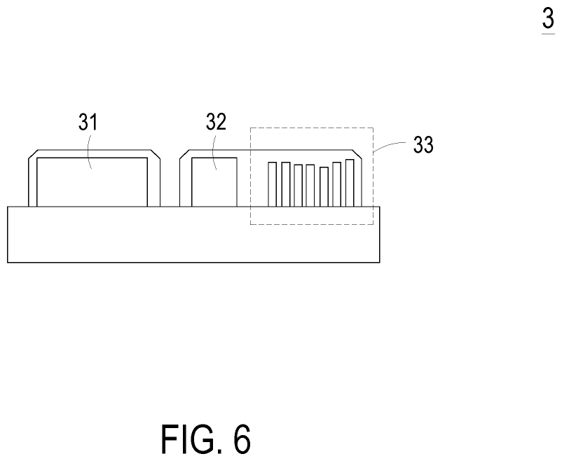

FIG. 6 is a schematic view illustrating a power supply connector of a power supply unit according to an embodiment of the present disclosure. As shown in FIG. 6, the power supply connector 3 is connected to the power supply circuit of the power supply unit shown in the above embodiments (i.e., the circuit of the power supply unit 1 of the first embodiment shown in FIG. 3 or 4 or the circuit of the power supply unit 2 of the second embodiment shown in FIG. 5). In detail, the power supply connector 3 includes a first part and a second part arranged sequentially. The first part includes a first contact area 31, which includes a plurality of pins electrically connected to the first ground terminal P2. The second part includes a second contact area 32 and a third contact area 33, the second contact area 32 includes a plurality of pins electrically connected to the first output terminal P1, and the third contact area 33 includes a plurality of pins, which may be electrically connected to at least one of the second output terminal P3, the second ground terminal P4 and the communication port P5. Further, the power supply connector 3 includes a gap between the first part and the second part, a distance is between the second contact area 32 and the third contact area 33 for ensuring enough creepage and clearance between the high voltage circuit and the low voltage and communication circuits under a maximum operating current.

In order to be adapted to both the isolation application and the non-isolation application, the telecom power system needs the power supply units with two different platforms.

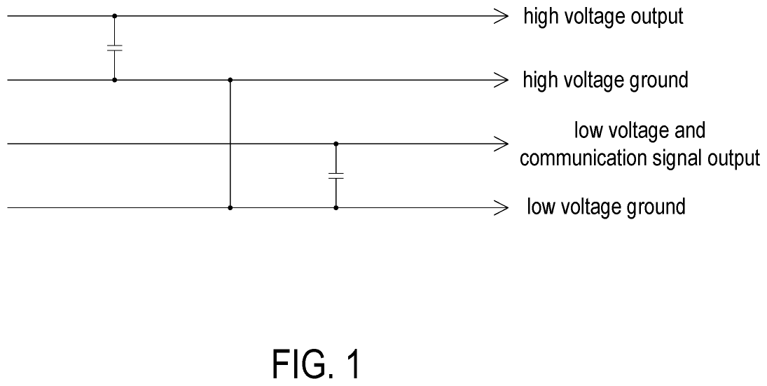

In the non-isolation platform, there is no isolation between the high voltage (e.g., 54V) circuit and the low voltage (e.g., 12V) and communication circuits. In specific, as shown in FIG. 1, the ground of the high voltage may be directly connected to the ground of the low voltage and communication signals. The non-isolation platform requires simple control wiring diagram, and all the grounds can join as one node which connects with floating chassis ground. The non-isolation platform may be applied to the non-isolation application such as M-CRPS (modular common redundant power supply).

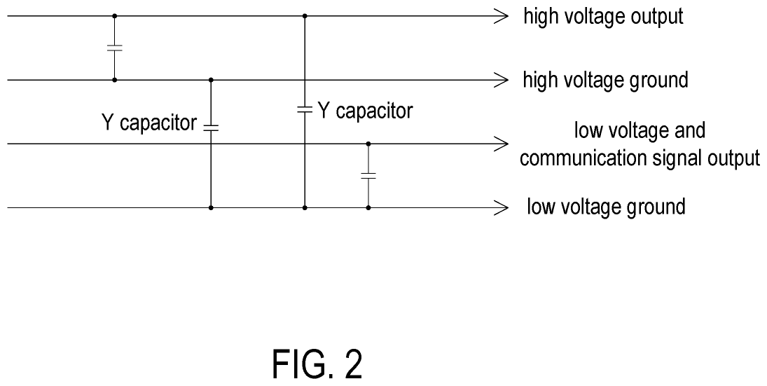

In the isolation platform, there is an isolation between the high voltage circuit and the low voltage and communication circuits. In specific, as shown in FIG. 2, the ground of the high voltage is isolated from the ground of the low voltage and communication signals. For example, the isolation may be realized by disposing Y capacitors. The isolation platform requires two difference system grounds and needs more spacing on creepage and clearance between the high voltage circuit and the low voltage and communication circuits. The isolation platform may be applied to the isolation application such as PoE (power over ethernet) requirement.

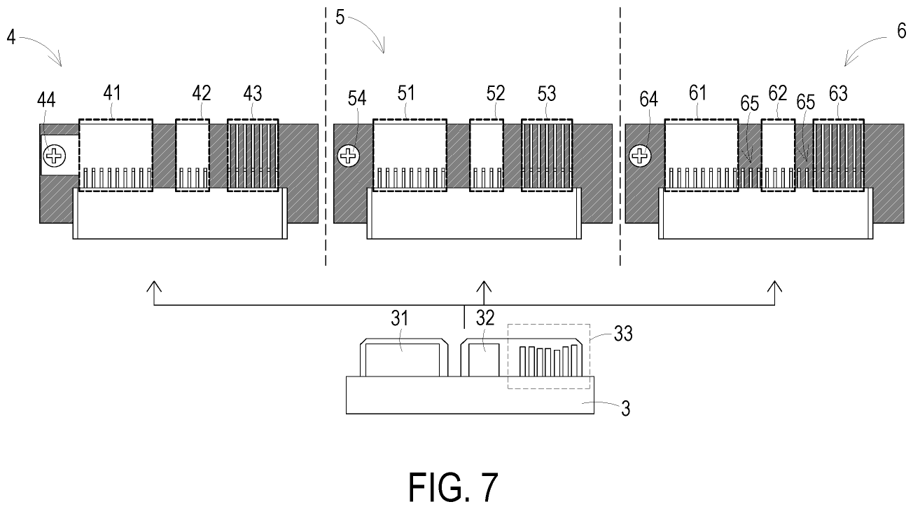

When the power supply unit is applied to an application system (e.g., isolation system or non-isolation system), the power supply connector 3 is connected to a system connector of the application system. FIG. 7 schematically shows various kinds of system connectors and application systems that the power supply connector of the present disclosure is applicable for. As shown in FIG. 7, the system connector 4 belongs to a non-isolation system. When the system connector 4 is connected to the power supply connector 3, first pins 41, second pins 42 and third pins 43 of the system connector 4 are respectively coupled to the pins of the first contact area 31, the pins of the second contact area 32 and the pins of the third contact area 33. In addition, the system connector 4 may further includes a ground pin (not shown) electrically connected to the system earth 44. The first pins 41 and the pins of the first contact area 31 are electrically connected to the system earth 44.

Another system connector 5 belongs to an isolation system. When the system connector 5 is connected to the power supply connector 3, first pins 51, second pins 52 and third pins 53 of the system connector 5 are respectively coupled to the pins of the first contact area 31, the pins of the second contact area 32 and the pins of the third contact area 33. The first pin 51 and the pins of the first contact area 31 are isolated from the system earth 54.

Another system connector 6 belongs to an isolation system. When the system connector 6 is connected to the power supply connector 3, first pins 61, second pins 62 and third pins 63 of the system connector 6 are respectively coupled to the pins of the first contact area 31, the pins of the second contact area 32 and the pins of the third contact area 33. The first pin 61 and the pins of the first contact area 31 are isolated from the system earth 64. In addition, the system connector 6 further include pins 65 between the first pins 61, the second pins 62 and the third pins 63, and the pins 65 are not connected to any power circuit.

Consequently, the power supply unit and the power supply connector of the present disclosure are applicable for both the isolation application and non-isolation application. In particular, there is no need to modify the circuit topology of the power supply unit or the layout of the power supply connector for applying to the applications with different isolation requirements.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power supply unit of a telecom power system, comprising:
a first port configured to provide a first voltage and comprising a first output terminal and a first ground terminal;
a second port configured to provide a second voltage and comprising a second output terminal and a second ground terminal, wherein the second voltage is lower than the first voltage, and the second ground terminal is isolated from the first ground terminal;
a processor having a reference point electrically connected to the second ground terminal and configured for system control, communication, and controlling power provided by the first port;
an amplifier unit having a reference point electrically connected to the first ground terminal; and
a communication module configured to transmit signals between the processor and the amplifier unit with electrical isolation.

2. The power supply unit according to claim 1, further comprising a communication port connected to the processor, wherein the processor receives control logic of starting or shutting down the power supply unit from the telecom power system and/or reports operation status of the power supply unit to the telecom power system through the communication port.

3. The power supply unit according to claim 1, wherein the processor comprises a digital signal processing microcontroller unit.

4. The power supply unit according to claim 1, wherein the amplifier unit comprises at least one operational amplifier each having a reference point electrically connected to the first ground terminal.

5. The power supply unit according to claim 1, further comprising a first converter used to convert a voltage source into the first voltage provided to the first port, wherein the processor provides a control signal to drive a switch circuit of the first converter through an optical isolation PWM driver or a driver transformer so as to control the power provided by the first port.

6. The power supply unit according to claim 1, further comprising a control circuit electrically connected to the processor, wherein the control circuit reports a status of power provided by the second port, and the control circuit controls the power provided by the second port according to a control signal provided by the processor.

7. The power supply unit according to claim 1, wherein the amplifier unit reports detection results, which reflect a status of the power provided by the first port and are obtained by detection circuits of the power supply unit, to the processor through the communication module.

8. The power supply unit according to claim 7, wherein the detection circuits comprise a current sensing circuit, an over-voltage-protection fault detection circuit, an over-current-protection fault detection circuit and/or a short-circuit detection circuit.

9. The power supply unit according to claim 7, wherein the communication module comprises at least one opto-coupler each comprising a transmitter connected to the amplifier unit and a receiver connected to the processor, and the at least one opto-coupler is configured to the transmit the detection results from the amplifier unit to the processor with electrical isolation.

10. The power supply unit according to claim 9, wherein the number of the at least one opto-coupler is determined according to the number of the detection circuits.
